(19) United States
(12) Patent Application Publication
(10) Pub. No.: US 2008/0026580 A1
(43) Pub. Date: Jan. 31, 2008

(54) Method For Forming Copper Metal Lines In Semiconductor Integrated Circuit Devices

(76) Inventor: In Cheol Baek, Daejeon (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/782,971

(22) Filed: Jul. 25, 2007

(30) Foreign Application Priority Data
Jul. 25, 2006 (KR) 10-2006-0069704

(51) Int. Cl. H01L 21/441

(52) U.S. Cl. 438/687; 257/E21.477

(57) ABSTRACT

A method of forming copper metal lines capable of improving surface coatability without forming overhangs of a diffusion barrier film for preventing diffusion of copper in an upper portion of a hole and preventing formation of a copper void is disclosed. The method includes coating a lower layer on a substrate, coating an interlayer insulating film to cover the lower layer, partially and selectively etching the interlayer insulating film to form a trench and a hole such that the lower layer is partially exposed by the hole, and forming diffusion barrier films for preventing diffusion of copper on the interlayer insulating film having the trench and the hole and on the lower layer partially exposed by the hole, wherein the step of forming diffusion barrier films includes forming a first diffusion barrier film for preventing diffusion of copper which is made of a tungsten nitride film and forming a second diffusion barrier film for preventing diffusion of copper which is made of tungsten. The step of forming a first diffusion barrier film includes a first cycle for exposing the substrate to gaseous WF₆ and B₂H₆ and a second cycle for exposing the substrate to NH₃.

### RELATED APPLICATION

The application is based upon and claims the benefit of priority to Korean Patent Application No. 10-2006-0069704, filed on Jul. 25, 2006, the entire contents of which are incorporated herein by reference.

### BACKGROUND

1. Technical Field

The present invention relates to a semiconductor technology, and more particularly to a method of forming copper metal lines wherein a diffusion barrier film which may prevent diffusion of copper is formed using atomic layer deposition.

2. Background

In a semiconductor integrated circuit (IC) device technology, an interconnection technology is used to form lines which connect circuits in the IC device, supply power, or transmit signals. The metal lines of the IC device have been made of aluminum. Along with the trend of high-integration and high-speed semiconductor devices, a line width is reduced to increase the line and contact resistances, which causes problems such as signal delay, power loss and electromigration (EM). Accordingly, copper metal lines are being intensively studied. For example, copper lines and low-K dielectric materials are commonly used in 0.13 μm logic devices, and copper lines are increasingly used in the high-integration memory.

Copper has a lower resistance than aluminum, i.e., about 62 percent of an aluminum resistance. Further, copper has a high resistance against electromigration (EM). Thus, copper has an excellent interconnection reliability in the high-integration and high-speed devices and excellent electroplating characteristics. Further, copper lines are formed with a higher yield than aluminum lines having the same design. On the other hand, since it is difficult to dry etch copper differently from aluminum, copper lines are generally formed through a double-damascene process for forming a damascene structure having a trench and a hole in an interlayer insulating layer. Further, since copper has a high diffusion speed, copper is usually trapped in a diffusion barrier film to prevent a transistor from being corroded.

Conventionally, in the copper interconnection process, a Ta/TaN film is mainly used as a diffusion barrier film for preventing diffusion of copper. A copper interconnection layer is formed on the diffusion barrier film using Electro Chemical Plating (ECP). In order to form the copper interconnection layer, first, a seed layer should be coated. A copper seed layer is formed using Physical Vapor Deposition (PVD). The copper seed layer, which serves as an electrode in the Electro Chemical Plating (ECP) process for forming the copper interconnection layer, conducts current from a cathode positioned on the edge of a wafer to an anode positioned in the center of the wafer. The current generates copper ions in a copper electroplating solution to perform copper plating.

Meanwhile, the diffusion barrier film for preventing diffusion of copper is also formed using Physical Vapor Deposition (PVD). In this case, there is a problem such that an overhang is formed in an upper portion of a hole as shown in FIG. 1.

FIG. 1 shows a partial cross-sectional view for explaining problems in the conventional copper interconnection process.

Referring to FIG. 1, an interlayer insulating film 10 is partially etched to form a hole 15. A copper barrier layer 12 for preventing diffusion of copper is formed on the interlayer insulating film 10 having the hole 15 using Physical Vapor Deposition (PVD). When the copper barrier layer 12 is formed by coating Ta/TaN-based metal using PVD, as shown in FIG. 1, the copper barrier layer has different thicknesses in the bottom and sidewall of the hole. Thus, there are problems such as poor surface coatability and overhangs 16, 18 generated, particularly, in an upper portion of the hole.

As the size of the hole becomes smaller, the overhang problem becomes more sever. Accordingly, a copper seed layer (not shown) formed on the copper barrier layer 12 is partially cut off, thereby resulting in a copper void, which is not plated with copper in the ECP process for forming the copper interconnection layer. The copper void deteriorates device characteristics.

### SUMMARY

Accordingly, the present invention is directed to a method of forming copper metal lines in semiconductor integrated circuit devices that addresses one or more problems due to limitations and disadvantages of the related art.

Additional advantages, features will be set forth in part in the detailed description which follows and in part will become apparent to those having ordinary skill in the art upon examination of the following or may be learned from practice of the invention. The advantages and features of the invention may be realized and attained by the structure particularly pointed out in the written description and claims hereof as well as in the appended drawings.

Accordingly, there is provided a method of forming copper metal lines includes coating a lower layer on a substrate, coating an interlayer insulating film to cover the lower layer, partially and selectively etching the interlayer insulating film to form a trench and a hole such that the lower layer is partially exposed by the hole, and forming diffusion barrier films for preventing diffusion of copper on the interlayer insulating film having the trench and the hole and on the lower layer partially exposed by the hole, wherein the step of forming diffusion barrier films includes forming a first diffusion barrier film for preventing diffusion of copper which is made of a tungsten nitride film and forming a second diffusion barrier film for preventing diffusion of copper which is made of tungsten. The step of forming a first diffusion barrier film includes a first cycle for exposing the substrate to gaseous WF₆ and B₂H₆ and a second cycle for exposing the substrate to NH₃.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments consistent with the invention and together with the description serve to explain the principles of the invention. In the drawings:

FIG. 1 shows a partial cross-sectional view for explaining problems in a conventional copper interconnection process, according to one exemplary embodiment.

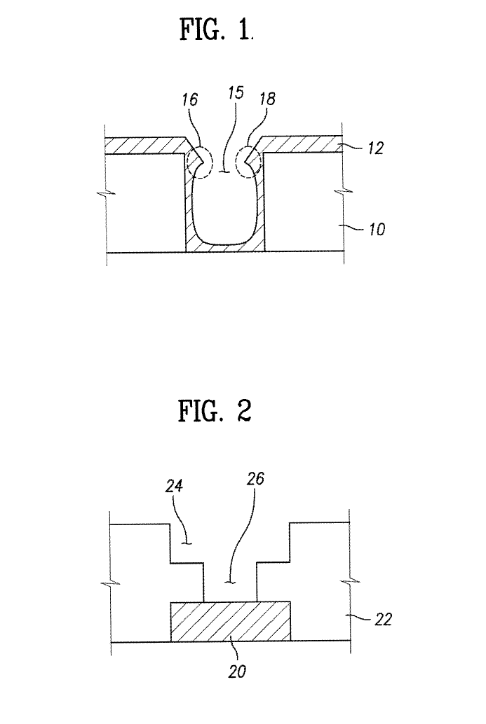

FIGS. 2 to 4 are partial cross-sectional views for explaining a method of forming copper metal lines according to an exemplary embodiment.

### DETAILED DESCRIPTION OF THE INVENTION

Reference will now be made in detail to exemplary embodiments of examples of which are illustrated in the accompanying drawings. Wherever possible, the same reference numbers will be used throughout the drawings to refer to the same or like parts.

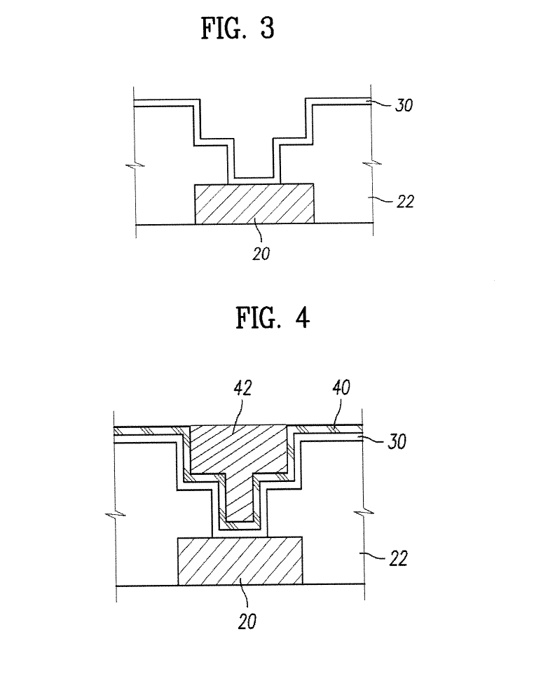

FIGS. 2 to 4 are partial cross-sectional views for explaining a method of forming copper metal lines consistent with the present invention.

Referring to FIG. 2, an interlayer insulating film 22 may be coated on a lower layer 20. The interlayer insulating film 22 may be primarily etched to form a trench 24. Then, the interlayer insulating film 22 may be secondarily etched to form a hole 26.

In order to form the trench 24 and the hole 26, a photoresist film (not shown) may be formed on the interlayer insulating film 22. A photolithography process may be performed to form a trench pattern and a hole pattern on the photoresist film. Then, the interlayer insulating film 22 may be selectively and partially etched using the trench pattern and the hole pattern as a mask. As shown in FIG. 2, the trench 24 and the hole 26 may have a double stepped structure. The trench 24 and the hole 26 may be formed through one photolithography process or may be sequentially formed through two photolithography processes.

For example, the lower layer 20 shown in FIG. 2 may be a copper metal layer. A portion of the upper surface of the lower layer 20 may be exposed by the hole 26.

FIGS. 3 and 4 show cross-sectional views showing structures having first and second diffusion barrier films for preventing diffusion of copper in a method of forming copper metal lines consistent with the present invention.

Referring to FIG. 3, a first diffusion barrier film 30 for preventing diffusion of copper, which is made of a tungsten nitride film, may be formed on the interlayer insulating film 22 having the trench 24 and the hole 26 of a double stepped structure. In this case, the first diffusion barrier film 30 may also be formed on the lower layer 20 which is partially exposed by the hole 26. In this embodiment, the first diffusion barrier film 30 may be formed using atomic layer deposition (ALD) or atomic layer epitaxy (ALE).

Atomic layer deposition (ALD) is a chemical thin film deposition method based on sequential saturative surface reactions. Atomic layer deposition (ALD) is different from chemical vapor deposition (CVD) in that vapor precursors are alternately injected into a substrate. Generally, there are two basic vapor deposition processes: physical vapor deposition (PVD) and chemical vapor deposition (CVD). In physical vapor deposition (PVD), a processing temperature is very low, whereas a thin film is coated with poor uniformity. In chemical vapor deposition (CVD), a thin film is coated with good uniformity, whereas a processing temperature is very high. Atomic layer deposition (ALD) may overcome the drawbacks of physical vapor deposition (PVD) and chemical vapor deposition (CVD) and has excellent coatability of a thin film.

In this embodiment, in order to form the first diffusion barrier film 30, a substrate having an interlayer insulating film with a trench and a hole may be loaded into a chamber (not shown). Then, the substrate may be exposed to gaseous WF₆ and B₂H₆. In this case, WF₆ is a first precursor and B₂H₆ is a reducing agent. However, Si₂H₆ may be used as a reducing agent instead of B₂H₆. Through such a process, i.e., a first cycle, a tungsten layer is formed on the surface of the substrate. The remainder of the precursor and the reducing agent left in the first cycle without reaction may be removed from the chamber. NH₃ serving as a second precursor may be injected into the chamber and the substrate exposed to NH₃. The tungsten layer formed in the first cycle may be converted into a tungsten nitride layer (WN layer) through a second cycle in which the substrate is exposed to NH₃. By repeating the first cycle and the second cycle, the first diffusion barrier film 30 having a specified thickness may be formed on the surface of the substrate.

For example, the first cycle and the second cycle may be performed under process conditions: temperature of 200˜400° C.; pressure of 10⁻³ ˜10⁻⁵ Torr; WF₆ flow rate of 10˜100 sccm; processing time of 1˜10 seconds.

A second diffusion barrier film 40 for preventing diffusion of copper may be formed on the first diffusion barrier film 30 as shown in FIG. 4. The second diffusion barrier film 40 and the first diffusion barrier film 30 may be formed through an in-situ process in the same chamber.

Meanwhile, an upper layer 42 may be formed on the second diffusion barrier film 40 shown in FIG. 4. In this case, the upper layer 42 is, for example, a copper metal layer. The second diffusion barrier film made of tungsten may be used as a copper seed layer serving as an electrode in an ECP process for forming the copper metal layer 42.

Consistent with the present invention, it is possible to form a diffusion barrier film for preventing diffusion of copper with excellent surface coatability and good uniformity without formation of overhangs of the diffusion barrier film in an upper portion of a hole. Further, it is possible to improve characteristics of semiconductor integrated circuit devices by preventing formation of a copper void in a copper interconnection layer.

According to the present invention, differently from a conventional process, a previously-formed tungsten layer may be used as a seed layer without additionally forming a copper seed layer. Thus, a step of forming a copper seed layer may be omitted, thereby simplifying a process.

Further, a tungsten nitride (WN) layer formed using ALD may be used as a diffusion barrier film and a tungsten (W) layer may be used as a seed layer. Accordingly, it is possible to form a diffusion barrier film with uniform surface coatability. It is also possible to form copper interconnection without a copper void even for a small hole.

It will be apparent to those skilled in the art that various modifications and variations may be made without departing from the spirit and scope consistent with the invention as defined by the appended claims.

What is claimed is:

1. A method of forming copper metal lines comprising:
coating a lower layer on a substrate;
coating an interlayer insulating film to cover the lower layer;
partially and selectively etching the interlayer insulating film to form a trench and a hole such that the lower layer is partially exposed by the hole; and
forming first and second diffusion barrier films for preventing diffusion of copper on the interlayer insulating film having the trench and the hole and on the lower layer partially exposed by the hole,
wherein the step of forming first and second diffusion barrier films includes repeating a first cycle for forming a tungsten layer on a surface of the substrate by exposing the substrate to a first precursor and a reducing agent and a second cycle for forming a tungsten nitride layer by exposing the formed tungsten layer to a second precursor.

2. The method according to claim 1, wherein the first and second diffusion barrier films are formed in a single chamber.

3. The method according to claim 1, wherein the first precursor is tungsten hexafluoride (WF₆), the reducing agent is diborane (B₂H₆), and the second precursor is ammonia (NH₃).

4. The method according to claim 1, wherein the first precursor is tungsten hexafluoride (WF₆), the reducing agent is disilane (Si₂H₆), and the second precursor is ammonia (NH₃).

5. The method according to claim 1, wherein of forming the first diffusion barrier film includes repeating the first cycle and the second cycle.

6. The method according to claim 3, wherein of forming the first diffusion barrier film includes repeating the first cycle and the second cycle.

7. The method according to claim 3, wherein the first cycle and the second cycle are performed at a temperature of 200 to 400° C. for 1 to 10 seconds.

8. The method according to claim 3, wherein the first cycle and the second cycle are performed at a pressure of 10⁻³ to 10⁻⁵ Torr.

9. The method according to claim 7, wherein the first cycle and the second cycle are performed at a pressure of 10⁻³ to 10⁻⁵ Torr.

10. The method according to claim 3, wherein the first cycle and the second cycle are performed at a WF₆ flow rate of 10 to 100 sccm.

11. The method according to claim 7, wherein the first cycle and the second cycle are performed at a WF₆ flow rate of 10 to 100 sccm.

12. The method according to claim 1, wherein the second diffusion barrier film made of tungsten is used as a copper seed layer for forming the copper metal lines on the second diffusion barrier film.
